(19) United States
(12) Patent Application Publication
(10) Pub. No.: US 2026/0038771 A1
(43) Pub. Date: Feb. 5, 2026

(54) Processing Apparatus and Shower Structure

(71) Applicant: Tokyo Electron Limited, Tokyo (JP)

(72) Inventors: Ikki KON, Kanagawa (JP); Hiroshi KONDO, Tokyo (JP)

(21) Appl. No.: 19/288,582

(22) Filed: Aug. 1, 2025

(30) Foreign Application Priority Data
Aug. 2, 2024 (JP) 2024-128135

(51) Int. Cl. H01J 37/32

(52) U.S. Cl. CPC H01J 37/3244; H01J 37/32357; H01J 37/32715; H01J 2237/334

(57) ABSTRACT

A processing apparatus for processing a peripheral edge portion of a processing target object with plasma comprises a support part configured to support the processing target object in a processing chamber and a shower structure located to face the processing target object. The shower structure includes a first gas hole formed in a first region facing a center of the processing target object and configured to discharge an inert gas, a partitioning part having an annular shape in plan view, and configured to partition the first region from a second region surrounding an outer circumference of the first region at a position facing an outer peripheral portion of the processing target object, and a second gas hole located in the second region and configured to discharge plasma. The partitioning part is formed to extend downward.

### CROSS-REFERENCE TO RELATED APPLICATIONS

This application claims priority to Japanese Patent Application No. 2024-128135 filed on Aug. 2, 2024, the entire contents of which are incorporated herein by reference.

### TECHNICAL FIELD

The present disclosure relates to a processing apparatus and a shower structure.

### BACKGROUND

Japanese Laid-open Patent Publication No. 2021-197244 discloses a plasma processing apparatus for performing plasma processing on an edge of a substrate. The plasma processing apparatus includes: a processing chamber; a substrate support member for supporting at least a portion of the substrate except the edge to be performed on the plasma processing in the processing chamber, to which a radio frequency (RF) power is supplied, and of which at least a side surface is made of a dielectric material; and an opposing dielectric member that is made of a dielectric material and provided to face the substrate support member. The plasma processing apparatus further includes a side ground electrode that has a ground potential and is provided at a position close to the substrate on the side of the substrate supported by the substrate support member so that electrical coupling occurs between the substrate and the edge surface of the substrate. In the plasma processing apparatus, an etching gas is supplied to the edge of the substrate. In addition, a gas channel is provided at the center of the opposing dielectric member, and an inert gas is supplied to the center of the substrate through the gas channel. Accordingly, the flow of the inert gas is generated from the center of the substrate toward the edge of the substrate, thereby preventing the etching gas from reaching the center of the substrate.

### SUMMARY

The technique of the present disclosure efficiently and uniformly processes a peripheral edge portion of a processing target object with plasma in a circumferential direction of the processing target object.

One aspect of the present disclosure provides a processing apparatus for processing a peripheral edge portion of a processing target object with plasma, comprising a processing chamber accommodating the processing target object, a support part configured to support the processing target object in the processing chamber, and a shower structure located to face the processing target object supported on the support part, wherein the shower structure includes a first gas hole formed in a first region facing a center of the processing target object supported by the support part and configured to discharge an inert gas, a partitioning part having an annular shape in plan view, and configured to partition the first region from a second region surrounding an outer circumference of the first region at a position facing an outer peripheral portion of the processing target object supported by the support part, and a second gas hole located in the second region and configured to discharge plasma, wherein the partitioning part is formed to extend downward, and the second gas hole is provided as a plurality of holes arranged in an annular shape along an outer circumference of the partitioning part in plan view, or formed in an annular shape along the outer circumference of the partitioning part in plan view.

### BRIEF DESCRIPTION OF THE DRAWINGS

FIG. 1 is a longitudinal cross-sectional view showing an outline of a configuration of a processing apparatus according to the present embodiment.

FIG. 2 is a partially enlarged view of FIG. 1.

FIG. 3 is a top view of a shower structure.

FIG. 4 is a bottom view of the shower structure.

FIG. 5 explains the main effect of the present embodiment.

FIG. 6 explains the main effect of the present embodiment.

FIG. 7 is a longitudinal cross-sectional view for explaining another example 1 of the shower structure.

FIG. 8 is a longitudinal cross-sectional view for explaining another example 2 of the shower structure.

FIG. 9 is a bottom view for explaining another example 2 of the shower structure.

FIG. 10 explains another example of a support portion.

FIG. 11 is a bottom view for explaining a modification of a second gas hole.

### DETAILED DESCRIPTION

Hereinafter, a processing apparatus and a shower structure according to the present embodiment will be described in detail with reference to the accompanying drawings. Further, throughout the specification and the drawings, like reference numerals will be given to like or corresponding parts and redundant description thereof will be omitted.

### <Processing Apparatus>

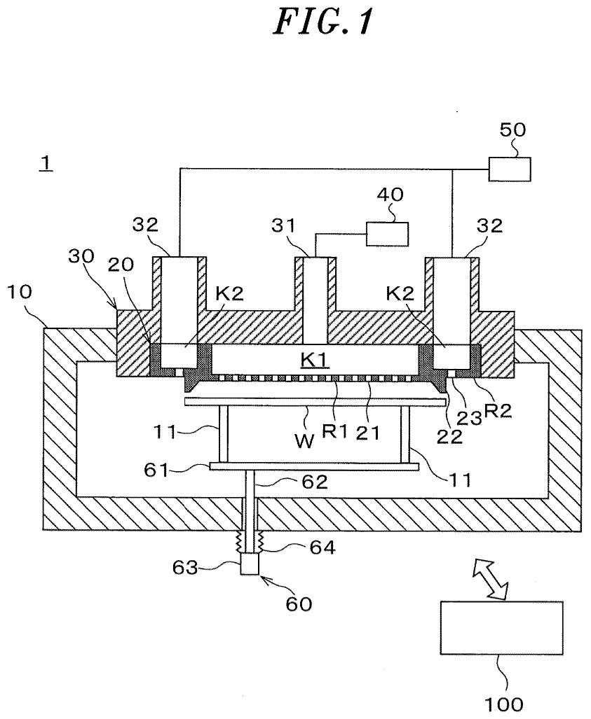

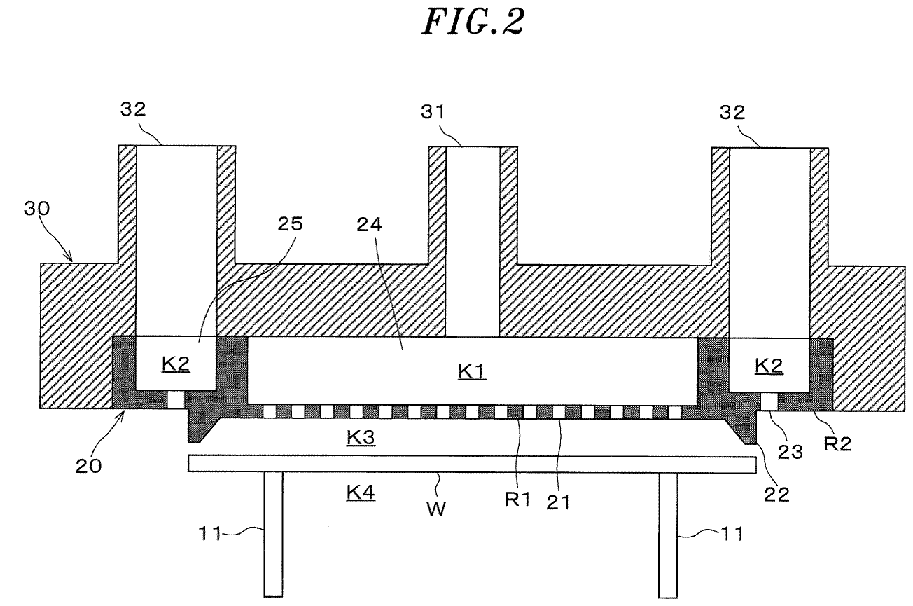

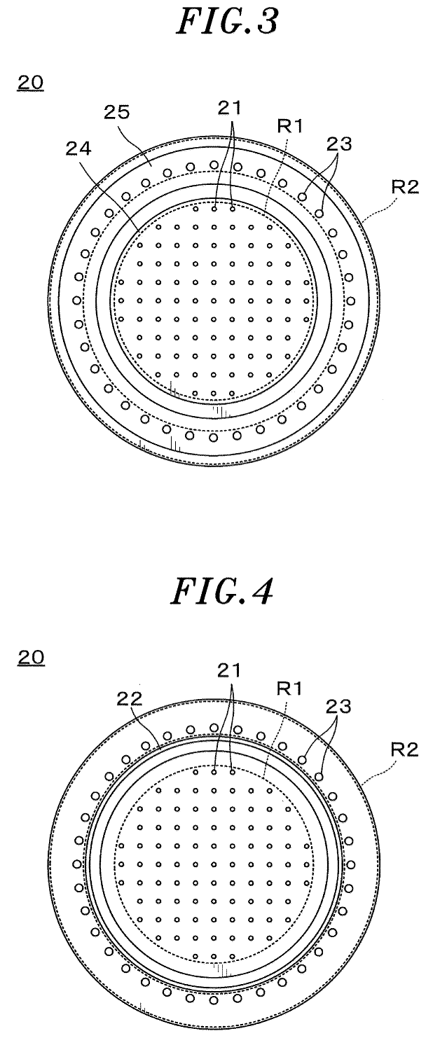

FIG. 1 is a longitudinal cross-sectional view showing an outline of a configuration of a processing apparatus according to the present embodiment. FIG. 2 is a partially enlarged view of FIG. 1. FIGS. 3 and 4 are top and bottom views of a shower structure to be described later, respectively.

The processing apparatus 1 in FIG. 1 processes a peripheral edge portion of a semiconductor wafer (hereinafter, referred to as “wafer”) W, which is a substrate to be processed, by plasma. Specifically, the processing apparatus 1 removes an unnecessary film formed on the peripheral edge portion of the wafer W. The processing apparatus 1 includes a processing chamber 10.

The processing chamber 10 accommodates the wafer W, and is configured to be depressurized. Therefore, an exhaust mechanism (not shown) for exhausting the inside of the processing chamber 10 is connected to the processing chamber 10. The exhaust mechanism is connected to the bottom wall of the processing chamber 10, for example. The processing chamber 10 is formed in a cylindrical shape and made of aluminum, for example. Further, the processing chamber 10 is grounded. A loading/unloading port (not shown) for the wafer W is provided on the sidewall of the processing chamber 10, and a gate valve (not shown) for opening and closing the loading/unloading port is provided at the loading/unloading port.

A plurality of (specifically, three or more) lifter pins 11 are provided as support portions in the processing chamber 10. The support portions support a processing target object in the processing chamber 10, and specifically support the processing target object such that both the front surface and the rear surface of the peripheral edge portion of the processing target object are exposed in the processing chamber 10. In the present disclosure, “peripheral edge portion” of the wafer W refers to a portion including at least the bevel portion and the peripheral end (APEX) of the wafer W.

The upper ends of the lifter pins 11 may be provided with electrodes (not shown) for electrically attracting the wafer W to the lifter pins 11.

The processing apparatus 1 further includes a shower structure 20 that faces the wafer W supported by the lifter pins 11. In one embodiment, the shower structure 20 constitutes the upper wall, i.e., the ceiling wall, of the processing chamber 10 that covers the upper part of the wafer W supported by the lifter pins 11, together with a support wall 30 that supports the shower structure 20.

As shown in FIG. 2, the shower structure 20 has a first gas hole 21 in a first region R1 that faces the center of the wafer W supported by the lifter pins 11. The first gas hole 21 discharges an inert gas such as argon gas or the like. The inert gas is discharged downward from the first gas hole 21. Specifically, the discharge direction is a vertically downward direction. In other words, the first gas hole 21 is provided to penetrate through the first region R1 in the shower structure 20 in the vertical direction. As shown in FIGS. 3 and 4, a plurality of first gas holes 21, for example, are provided in the first region R1. Specifically, the plurality of first gas holes 21 are provided along two horizontal directions orthogonal to each other across substantially the entire surface of the circular first region R1 having an area slightly smaller than that of the wafer W. As shown in FIG. 1, each of the first gas holes 21 is connected to an inert gas supply source 40 through a gas channel 31 (to be described later) in the support wall 30. Specifically, each of the first gas holes 21 is connected to the inert gas supply source 40 through a diffusion space K1 and the gas channel 31 in the support wall 30. The diffusion space K1 is a channel that is connected to the first gas holes 21 from the top. The inert gas from the gas channel 31 in the support wall 30 is diffused in the diffusion space K1, and is supplied to each of the first gas holes 21. The diffusion space K1 is formed in a disc shape, for example.

The shower structure 20 has a partitioning part 22 formed in an annular shape in plan view (specifically, circular ring shape that is concentric with the wafer W in plan view) for partitioning the first region R1 and a second region R2 surrounding the outer circumference of the first region R1 at a position facing the outer peripheral portion of the wafer W supported by the lifter pins 11. In the present disclosure, “outer peripheral portion” of the wafer W refers to a portion including the peripheral edge portion of the wafer W and a portion located slightly inside the peripheral edge portion (for example, a portion within 10 mm from the peripheral end surface of the wafer W). Therefore, at a position facing the outer peripheral portion of the wafer W supported by the lifter pins 11, the partitioning part 22 described above may be provided across the peripheral edge portion of the wafer W and a portion located slightly inside the peripheral edge portion in plan view, or may be provided to overlap only the peripheral edge portion of the wafer W in plan view.

Further, the entire partitioning part 22 may not overlap the outer peripheral portion of the wafer W in plan view. Only a part of the partitioning part 22 may overlap the outer peripheral portion of the wafer W supported by the lifter pins 11 in plan view as long as the partitioning part 22 provides effects to be described below. Therefore, the outermost circumference of the partitioning part 22 may be located outside the peripheral edge of the wafer W supported by the lifter pins 11, and the innermost circumference of the partitioning part 22 may be located inside the outer peripheral portion of the wafer.

The partitioning part 22 is formed to extend downward, i.e., to protrude downward. Specifically, the partitioning part 22 is formed to extend downward toward the outer peripheral portion of the wafer W supported by the lifter pins 11. Accordingly, the partitioning part 22 is close to the wafer W at the outer peripheral portion of the wafer W.

In one example, the outer peripheral surface of the partitioning part 22 extends vertically in cross-sectional view, and coincides with the peripheral end surface of the wafer W supported by the lifter pins 11 in plan view.

In one example, the inner peripheral surface of the partitioning part 22 is an inclined surface that is lowered outward in cross-sectional view, and the upper end of the inner peripheral surface of the partitioning part 22 is located inside the outer peripheral portion of the wafer W supported by the lifter pins 11, and the lower end thereof is located above the outer peripheral portion of the wafer W.

Further, the shower structure 20 has second gas holes 23 in the second region R2 described above. The second gas holes 23 discharge plasma that is an etchant. As shown in FIG. 4, a plurality of second gas holes 23 are arranged in an annular shape along the outer circumference of the partitioning part 22 in plan view. As shown in FIG. 1, each of the second gas holes 23 is connected to a remote plasma supply source 50 installed outside the processing chamber 10 through a gas channel 32 (to be described later) in the support wall 30. Specifically, each of the second gas holes 23 is connected to the remote plasma supply source 50 through a diffusion space K2 and the gas channel 32 in the support wall 30. The diffusion space K2 is a channel that is connected to the second gas holes 23 from the top. The plasma from the gas channel 32 in the support wall 30 is diffused in the diffusion space K2, and is supplied to each of the second gas holes 23. The diffusion space K2 is formed in a circular ring shape that is concentric with the diffusion space K1, for example.

Further, the remote plasma supply source 50 supplies reactive plasma as plasma, specifically, radicals such as oxygen radicals or the like. For example, the remote plasma supply source 50 can activate an inert gas such as argon gas and an oxygen-containing gas such as oxygen gas, which are supplied to the remote plasma supply source 50, with plasma to form oxygen radicals.

The discharge direction of the plasma from the second gas holes 23 is common to all the second gas holes 23, for example, and is a vertically downward direction. In other words, all the second gas holes 23 are vertical holes for discharging plasma vertically downward, for example, and are formed to penetrate through the second region R2 in the shower structure 20 in the vertical direction.

However, if it is difficult to form all the second gas holes 23 as vertical holes as described above due to the positional relationship between the shower structure and other components in the processing apparatus 1, some of the plurality of second gas holes 23 may be formed as oblique holes for discharging plasma obliquely downward. In this case, it is preferable that the oblique holes are formed to discharge plasma obliquely downward, which is parallel to the tangential direction of the circle centered on the center of the wafer W supported by the lifter pins 11 at the positions of the oblique holes, in plan view. The second gas holes 23 formed as oblique holes are formed to penetrate through the second region R2 in the shower structure 20 in the obliquely downward direction. Since the oblique holes constituting the second gas holes 23 are formed as described above, it is possible to suppress the plasma from the second gas holes 23 from moving toward the center of the wafer W supported by the lifter pins 11.

Since vertical holes can shorten the channel length compared to oblique holes, it is preferable to form all the second gas holes 23 as vertical holes in view of preventing the plasma from being deactivated while passing through the second gas holes 23.

In order to prevent the plasma from being deactivated while passing through the second gas holes 23, each of the second gas holes 23 is formed to be greater than the first gas holes 21. In other words, each of the second gas holes 23 has a large diameter. The diameter of the second gas holes 23 is 2 mm or more, for example.

Further, the distance from the second gas holes 23 to the wafer W supported by the lifter pins 11 is greater than the distance from the first gas holes 21 to the wafer W. In other words, the second gas holes 23 are located at a position higher than the first gas holes 21.

Further, the second gas holes 23 are provided at positions that do not overlap the wafer W supported by the lifter pins 11 in plan view. In other words, the second gas holes 23 are provided outside the peripheral edge of the wafer W in plan view. The distance of each second gas hole 23 from the peripheral edge of the wafer W is set such that the peripheral edge of the wafer W can be efficiently processed by the plasma from the second gas holes 23.

The shower structure 20 further includes recesses 24 and 25 as shown in FIG. 2. Each of the recesses 24 and 25 is recessed downward and opened upward.

As shown in FIG. 3, the recess 24 is formed in a circular shape in plan view. The above-described disc-shaped diffusion space K1 is formed by blocking the upper opening of the recess 24 with the support wall 30.

The recess 25 is formed in an annular shape in plan view (specifically, circular ring shape in plan view). The annular diffusion space K2 is formed by blocking the upper opening of the recess 25 with the support wall 30.

As shown in FIGS. 1 and 2, the support wall 30 has gas channels 31 and 32 therein.

The gas channel 31 is connected to the diffusion space K1, and is formed to extend upward (specifically, vertically upward) from the center of the diffusion space K1 in plan view.

A plurality of gas channels 32 are provided along the diffusion space K2 in plan view. Each of the gas channels 32 is connected to the diffusion space K2, and is formed to extend upward (specifically, vertically upward).

Further, each of the shower structure 20 and the support wall 30 is made of aluminum, for example.

The processing apparatus 1 further includes a lifting mechanism 60 for raising and lowering the lifter pins 11. The lifting mechanism 60 includes, e.g., a holding member 61 for collectively holding the lifter pins 11, a support column 62 for supporting the holding member 61 from the bottom, and a driving mechanism 63 for generating a driving force for raising and lowering the support column 62. The support column 62 penetrates through the bottom wall of the processing chamber 10, and is connected to the driving mechanism 63 provided outside the processing chamber 10. As the support column 62 is raised and lowered by the operation of the driving mechanism 63, the holding member 61 and the lifter pins 11 are raised and lowered. As a result, the wafer W can be transferred between the lifter pins 11 and a transfer mechanism outside the apparatus, and the distance between the wafer W supported by the lifter pins 11 and the partitioning part 22 of the shower structure 20 can be adjusted.

A bellows 64 is provided between the driving mechanism 63 and the portion of the bottom wall of the processing chamber 10 through where the support column 62 penetrates to surround the outer circumference of the support column 62. Accordingly, the airtightness of the processing chamber 10 is maintained.

Further, the lifting mechanism 60 is controlled by a controller 100 to be described later.

The processing apparatus 1 configured as above includes at least one controller 100. The controller 100 processes computer-executable instructions that cause the processing apparatus 1 to execute various steps described in the present disclosure. The controller 100 may be configured to control individual components of the processing apparatus 1 to execute various steps described herein. In one embodiment, the controller 100 may be partially or entirely included in the processing apparatus 1. The controller 100 may include a processing part, a storage part, and a communication interface. The controller 100 is realized by a computer, for example. The processing part may be configured to read a program that provides logic or routines that enable various control operations to be performed from the storage part, and to perform various control operations by executing the read program. The program may be stored in the storage part in advance, or may be acquired via a medium when necessary. The acquired program is stored in the storage part, and is read from the storage part and executed by the processing part. The medium may be various storage media readable by a computer, or may be a communication line connected to the communication interface. The storage medium may be a temporary storage medium or a non-temporary storage medium. The processing part may be a central processing unit (CPU) or one or more circuits. The storage part may include a random access memory (RAM), a read only memory (ROM), a hard disk drive (HDD), a solid state drive (SSD), or a combination thereof. The communication interface may communicate with the processing apparatus 1 via a communication line such as a local area network (LAN) or the like.

### <Example of Processing Performed by Processing Apparatus 1>

An example of processing performed using the processing apparatus 1 will be described. Further, it is assumed that the wafer W to be processed in the following processing has been subjected to an etching process (cleaning process).

### (Step S1: Loading of Wafer W)

For example, first, the wafer W is loaded into the processing chamber 10.

Specifically, after the wafer W supported by a transfer mechanism provided outside the processing apparatus 1 is loaded into the processing chamber 10, the lifter pins 11 are raised, and the height of the wafer W supported by the lifter pins 11 becomes a transfer height. As a result, the wafer W is transferred from the transfer mechanism to the lifter pins 11. Next, the transfer mechanism retracts from the processing chamber 10, and the lifter pins 11 are raised. As a result, the height of the wafer W supported by the lifter pins 11 becomes a processing height, and the distance from the outer peripheral portion of the wafer W to the partitioning part 22 of the shower structure 20 becomes a predetermined distance. Further, after the transfer mechanism retracts, the inside of the processing chamber 10 is depressurized to a predetermined vacuum level by an exhaust mechanism (not shown).

### (Step S2: Cleaning)

Then, the film formed on the peripheral edge portion of the wafer W is removed by plasma.

Specifically, radicals such as oxygen radicals from the remote plasma supply source 50 are supplied into the processing chamber 10 from the second gas holes 23 of the shower structure 20. The films formed on the front and rear surfaces of the peripheral edge portion of the wafer W are removed by the radicals. In other words, the peripheral edge portion of the wafer W is cleaned.

Simultaneously with the supply of radicals, an inert gas such as argon gas from the supply source 40 is discharged from each of the first gas holes 21 of the shower structure 20 toward the wafer W supported by the lifter pins 11. Accordingly, the flow of inert gas toward the outside (of the wafer W) is formed in the gap between the partitioning part 22 of the shower structure 20 and the outer peripheral portion of the wafer W (specifically, between the bottom surface of the partitioning part 22 and the outer peripheral portion of the front surface of the wafer W). As a result, the radicals from the second gas holes 23 are prevented from moving toward the center of the wafer W through the gap, and the removal of the film formed at the center of the wafer W by the radicals is suppressed.

For example, when a predetermined period of time elapses from the start of the supply of radicals, the supply of radicals and the supply of inert gas are stopped, and the cleaning of the peripheral edge portion of the wafer W is completed.

### (Step S3: Unloading of Wafer W)

Then, the wafer W is unloaded from the processing chamber 10.

Specifically, the wafer W is unloaded from the processing chamber 10 in the reverse order of step S1.

Accordingly, a series of processes for one wafer W is completed, and a series of processes for a next wafer W is performed.

### Main Effects of Present Embodiment

As described above, in the present embodiment, the processing apparatus 1 for processing the peripheral edge portion of the wafer W with plasma includes the processing chamber 10 accommodating the wafer W, and the lifter pins 11 for supporting the wafer W in the processing chamber 10. Further, in the present embodiment, the processing apparatus 1 includes the shower structure 20 that is provided to face the wafer W supported by the lifter pins 11. Further, in the present embodiment, the shower structure 20 includes the first gas holes 21, the partitioning part 22, and the second gas holes 23. The first gas holes 21 are provided in the first region R1 facing the center of the wafer W supported by the lifter pins 11, and discharge an inert gas. The partitioning part 22 is formed in an annular shape in plan view, and partitions the first region from the second region R2 surrounding the outer circumference of the first region R1 at the position facing the outer peripheral portion of the wafer W supported by the lifter pins 11. The second gas holes 23 are provided in the second region R2 of the shower structure 20, and discharge plasma. In other words, in the present embodiment, the plasma is discharged from the position above the wafer W supported by the lifter pins 11. Therefore, in accordance with the present embodiment, unlike the case in which the plasma is discharged from the side portion of the wafer W supported by the lifter pins 11, it is possible to reduce the ratio of plasma that moves to a position below the wafer W and thus cannot contribute to the cleaning of the peripheral edge portion of the wafer W.

Further, in the present embodiment, the partitioning part 22 is formed to extend downward. Further, the plurality of second gas holes 23 are arranged in an annular shape along the outer circumference of the partitioning part 22 in plan view. Therefore, the plasma from the second gas holes 23 can be prevented from being deactivated by the partitioning part 22, compared to when the partitioning part 22 is formed to extend obliquely downward toward the outer peripheral portion of the wafer W, and the second gas holes 23 are formed at positions overlapping the partitioning part 22 in plan view, unlike the present embodiment.

Hence, in accordance with the present embodiment, the ratio of the plasma, i.e., the etchant, from the second gas holes 23, which contributes to the cleaning of the peripheral edge portion of the wafer W, can be increased.

Further, as described above, the plurality of second gas holes 23 are arranged in an annular shape along the outer circumference of the partitioning part 22 in plan view, so that the plasma can be uniformly supplied to the peripheral edge portion of the wafer W in the circumferential direction of the wafer W.

In accordance with the present embodiment, the peripheral edge portion of the wafer W can be efficiently and uniformly processed with plasma in the circumferential direction of the wafer W.

In the following description, “circumferential direction” refers to the circumferential direction of the wafer W supported by the lifter pins 11.

Further, in accordance with the present embodiment, the partitioning part 22 is formed to extend downward, so that a space K3 between the first region R1 where the first gas holes 21 of the shower structure 20 are provided and the surface of the wafer W supported by the lifter pins 11 is wide. Therefore, the inert gas discharged from the first gas holes 21 is diffused in the space K3 and then directed toward the gap between the partitioning part 22 of the shower structure 20 and the outer peripheral portion of the wafer W. Hence, the outward flow of the inert gas in the gap can become more uniform in the circumferential direction.

Further, in accordance with the present embodiment, the partitioning part 22 is formed to extend downward and the above-described space K3 is wide, so that the pressure difference between a space K4 below the wafer W supported by the lifter pins 11 and the space K3 is small. Therefore, it is possible to suppress deformation of the wafer W due to the pressure difference.

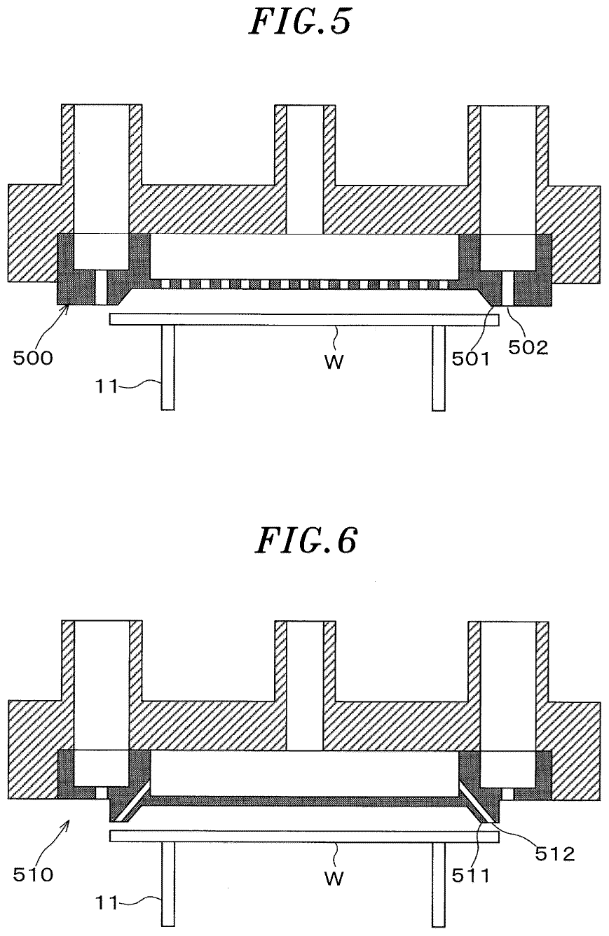

Further, the state in which the partitioning part 22 is formed to extend downward as described above indicates that the second gas holes 23 are located above the lower end of the partitioning part 22. Therefore, as shown in FIG. 5, the following effects are obtained compared to a case in which a portion 501 of the shower structure 500 that faces the outer peripheral portion of the wafer W supported by the lifter pins 11 protrudes downward and the lower ends of plasma discharge holes 502 are located at the same height as the bottom surface of the portion 501. In other words, in the present embodiment, the distance from the plasma discharge holes (the second gas holes 23 in the present embodiment) to the peripheral edge portion of the wafer W supported by the lifter pins 11 is longer than that in the case shown in FIG. 5. Therefore, the plasma from the plasma discharge holes (the second gas holes 23 in the present embodiment) can be supplied to the peripheral edge portion of the wafer W more uniformly in the circumferential direction, which makes it possible to suppress the non-uniformity of the amount of film removed by the plasma at the peripheral edge portion of the wafer W in the circumferential direction. In other words, it is possible to suppress the formation pattern of the plasma discharge holes (the second gas holes 23 in the present embodiment) from being transferred to the processing result by the plasma from the corresponding discharge holes.

Further, the state in which the partitioning part 22 is formed to extend downward as described above also indicates that the first gas holes 21 are located above the lower end of the partitioning part 22. Therefore, as shown in FIG. 6, the following effects are obtained compared to the case in which a portion 511 of the shower structure 510 that faces the outer peripheral portion of the wafer W supported by the lifter pins 11 protrudes downward and inert gas discharge holes 512 are opened at the lower end of the portion 511. In other words, in the present embodiment, the distance from the inert gas discharge holes (the first gas holes 21 in the present embodiment) to the peripheral edge portion of the wafer W supported by the lifter pins 11 is longer than that in the case shown in FIG. 6. Therefore, the inert gas from the inert gas discharge holes (the first gas holes 21 in the present embodiment) can be supplied to the peripheral edge portion of the wafer W more uniformly in the circumferential direction, which makes it possible to suppress the non-uniformity of the amount of film removed by the plasma at the peripheral edge portion of the wafer W in the circumferential direction. In other words, it is possible to suppress the formation pattern of the inert gas discharge holes (the first gas holes 21 in the present embodiment) from being transferred to the processing result by the plasma.

Further, in the present embodiment, the distance from the second gas holes 23 to the wafer W supported by the lifter pins 11 is longer than the distance from the first gas holes 21 to the wafer W. Therefore, in the present embodiment, the plasma from the second gas hole 23 can be more uniformly supplied to the peripheral edge portion of the wafer W in the circumferential direction compared to the case in which the distance from the second gas holes 23 to the wafer W supported by the lifter pins 11 is shorter than the distance from the first gas holes 21 to the wafer W. In other words, it is possible to suppress the formation pattern of the second gas holes 23 from being transferred to the processing result by the plasma from the second gas holes 23.

Further, in the present embodiment, the distance (first distance) from the first gas holes 21 of the shower structure 20 to the wafer W supported by the lifter pins 11, the distance (second distance) from the partitioning part 22 of the shower structure 20 to the wafer W, and the distance (third distance) from the second gas holes 23 of the shower structure 20 to the wafer W can be changed independently. Further, the first to third distances can be changed by changing the design of the shower structure 20 and adjusting the height of the lifter pins 11 supporting the wafer W, for example.

Further, in the present embodiment, the inner peripheral surface of the partitioning part 22 of the shower structure 20 is an inclined surface that becomes lower outward in cross-sectional view. Therefore, in the present embodiment, it is possible to suppress the inert gas from the first gas holes 21 from stagnating in the above-described space K3, compared to the case in which the inner peripheral surface extends vertically in cross-sectional view. Therefore, it is possible to suppress the inert gas supplied to the peripheral edge portion of the wafer W supported by the lifter pins 11 from becoming non-uniform in the circumferential direction as a result of the gas stagnation. In addition, it is possible to suppress the plasma from the second gas holes 23 from entering the space K3 through the gap between the peripheral edge portion of the wafer W and the partitioning part 22 of the shower structure 20 due to the vortex generated in the space K3 by the gas stagnation.

Further, in the present embodiment, the plurality of first gas holes 21 are provided. Therefore, the inert gas from the first gas holes 21 can be supplied more uniformly in the circumferential direction to the peripheral edge portion of the wafer W supported by the lifter pins 11, compared to the case where there is only one first gas hole 21. In addition, the density at which the inert gas from the first gas holes 21 collides with the wafer W can be reduced, so that the deformation of the wafer W due to the collision can be suppressed.

### <Another Example 1 of Shower Structure>

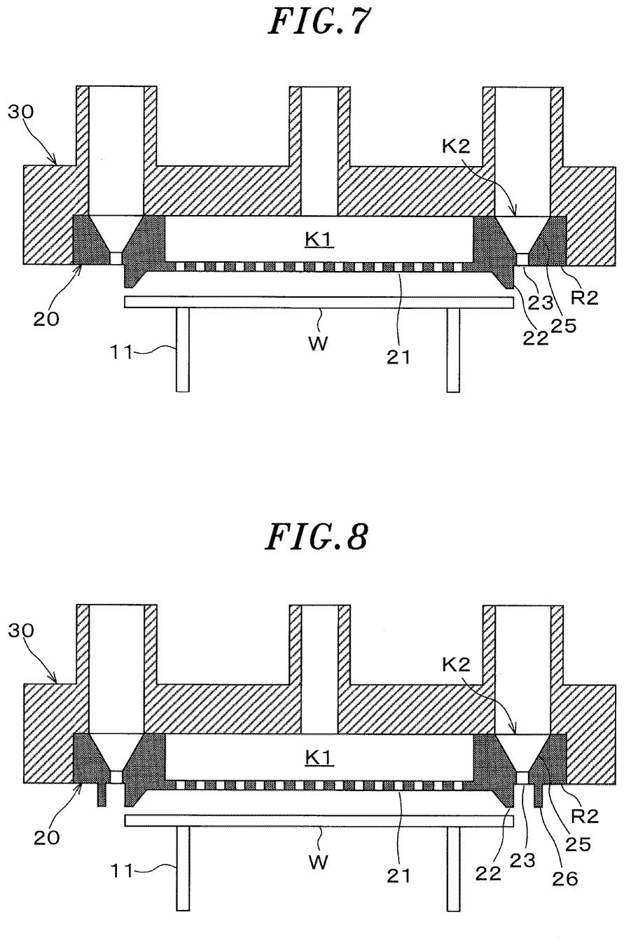

FIG. 7 is a longitudinal cross-sectional view explaining another example 1 of the shower structure.

As shown in FIG. 7, the diffusion space K2, which is the channel connected to the second gas holes 23 of the shower structure 20, may be formed in a tapered shape that becomes narrow toward the second gas holes 23 in cross-sectional view. Specifically, the recesses 25 of the shower structure 20 that constitute the diffusion space K2 may be formed in a tapered shape that becomes narrow toward the second gas holes 23 in cross-sectional view.

Accordingly, it is possible to suppress the plasma from the gas channel 32 from being deactivated by the collision with the wall surface of the shower structure that constitutes the recesses 25.

### <Another Example of Shower Structure 2>

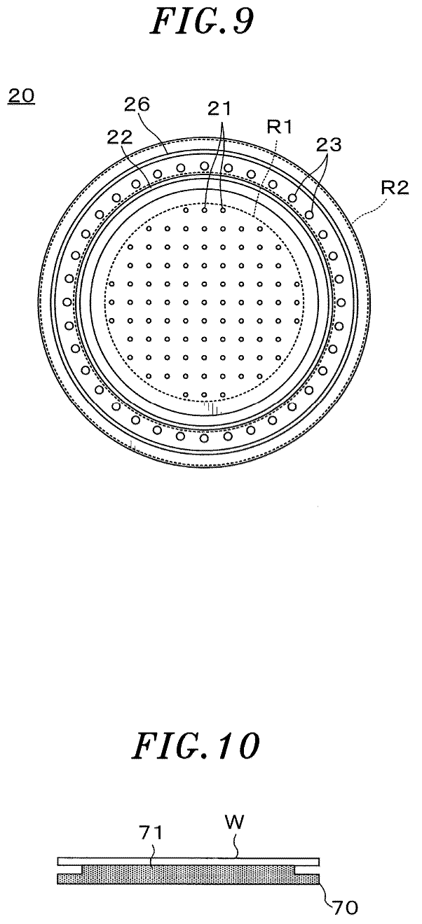

FIGS. 8 and 9 are a longitudinal cross-sectional view and a bottom view explaining another example of the shower structure 2, respectively.

As shown in FIGS. 8 and 9, the shower structure 20 may have a plasma collecting portion 26 formed in the second region R2 to extend downward.

The plasma collecting portion 26 is provided to collectively surround the outer circumferences of the second gas holes 23 arranged in an annular shape in plan view.

The plasma collecting portion 26 can suppress the plasma discharged from the second gas holes 23 from spreading outward. Therefore, the plasma from the second gas holes 23 can contribute more efficiently to the cleaning of the peripheral edge portion of the wafer W supported by the lifter pins 11. Further, compared to when the second gas holes 23 are simply longer, it is possible to suppress the plasma from being deactivated before the plasma reaches the peripheral edge portion of the wafer W, and also possible to suppress the formation pattern of the second gas holes 23 from being transferred to the processing result.

The lower end of the plasma collecting portion 26 may be located below the wafer W positioned at the processing height described above, and specifically, may be located below the backside of the wafer W. Accordingly, the plasma from the second gas holes 23 can contribute more efficiently to the cleaning of the backside of the wafer W as well as the cleaning of the rear surface of the peripheral edge portion of the wafer W.

### <Modification of Support Portion>

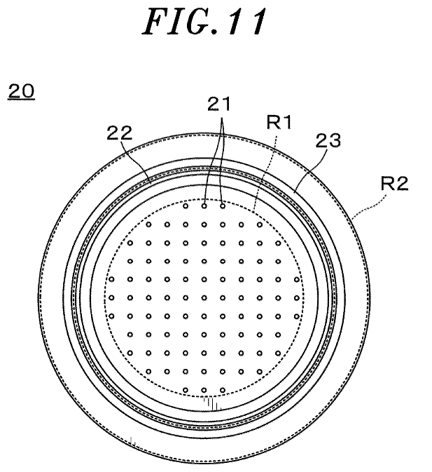

FIG. 10 is a diagram for explaining another example of the support portion for supporting the wafer W.

In the above example, the plurality of lifter pins 11 that support the wafer W at points are provided as the support portions. Instead, as shown in FIG. 11, a stage 70 that supports the wafer W on a surface may be provided. The stage 70 has a cylindrical part 71 with a diameter smaller than that of the wafer W, and supports the wafer W with the cylindrical part 71 such that the outer peripheral portion of the wafer W protrudes from the cylindrical part 71.

By using the stage 70, the deformation of the wafer W due to the pressure difference described above can be avoided.

Further, the stage 70 is configured to be movable up and down, similarly to the lifter pins 11.

A temperature control mechanism for adjusting the temperature of the wafer W supported on the stage may be provided in the stage 70. The temperature control mechanism is a resistance heater or a channel for a temperature control medium. Further, the stage 70 may be provided with an electrode for electrically attracting the wafer W to the stage.

By providing the lifter pins 11 at the stage 70, the processing height of the wafer W may be adjusted by either the stage 70 or the lifter pins 11.

### <Modification of Second Gas Holes 23>

FIG. 11 is a bottom view for explaining a modification of the second gas holes 23.

As shown in FIG. 11, the second gas holes 23 may be formed in an annular shape (specifically, circular ring shape) along the outer circumference of the partitioning part 22 in plan view.

Further, the second gas holes 23 may not be formed in a circular ring shape, and each of the plurality of second gas holes 23 may be formed in an arc shape, and the plurality of second gas holes 23 may be arranged to form an annular shape (specifically, a circular ring shape) as a whole.

It should be noted that the above-described embodiments are illustrative in all respects and are not restrictive. The above-described embodiments may be omitted, replaced, or changed in various forms without departing from the scope of the appended claims and the gist thereof. For example, the components of the above-described embodiments can be randomly combined. The effects of the components for arbitrary combination can be obtained from the corresponding arbitrary combination, other effects apparent to those skilled in the art can also be obtained.

The effects described in the present specification are merely explanatory or exemplary, and are not restrictive. In other words, in the technique related to the present disclosure, other effects apparent to those skilled in the art can be obtained from the description of the present specification in addition to the above-described effects or instead of the above-described effects.

The following configuration examples are also included in the technical scope of the present disclosure.
(1) A processing apparatus for processing a peripheral edge portion of a processing target object with plasma, comprising:
a processing chamber accommodating the processing target object;
a support part configured to support the processing target object in the processing chamber; and
a shower structure located to face the processing target object supported on the support part;
wherein the shower structure includes:
   a first gas hole formed in a first region facing a center of the processing target object supported by the support part and configured to discharge an inert gas;
   a partitioning part having an annular shape in plan view, and configured to partition the first region from a second region surrounding an outer circumference of the first region at a position facing an outer peripheral portion of the processing target object supported by the support part; and
   a second gas hole located in the second region and configured to discharge plasma,
wherein the partitioning part is formed to extend downward, and
the second gas hole is provided as a plurality of holes arranged in an annular shape along an outer circumference of the partitioning part in plan view, or formed in an annular shape along the outer circumference of the partitioning part in plan view.
(2) The processing apparatus of (1), wherein a distance from the second gas hole to the processing target object supported by the support part is longer than a distance from the first gas hole to the processing target object supported by the support part.
(3) The processing apparatus of (1) or (2), wherein the shower structure further includes:
a channel connected to the second gas hole from the top,
wherein the channel is formed in a tapered shape that becomes narrow toward the second gas hole in cross-sectional view.
(4) The processing apparatus of any one of (1) to (3), wherein the shower structure further includes:
a plasma collecting portion formed in the second region to extend downward,
wherein the plasma collecting portion collectively surrounds the outer circumferences of the plurality of second gas holes arranged in an annular shape in plan view, or surrounds the outer circumference of the second gas hole formed in an annular shape in plan view.
(5) The processing apparatus of any one of (1) to (4), wherein the plurality of second gas holes are arranged in an annular shape along the outer circumference of the partitioning part in plan view,
the plurality of second gas holes include vertical holes and oblique holes,
the vertical holes discharge plasma vertically downward, and
the oblique holes discharge plasma obliquely downward, which is parallel to a tangential direction of a circle centered on the center of the processing target object supported by the support part at the positions of the oblique holes, in plan view.
(6) The processing apparatus of any one of (1) to (5), wherein the second gas hole is provided at a position that does not overlap the processing target object supported by the support in plan view.
(7) The processing apparatus of any one of (1) to (6), wherein the plasma is supplied from a remote plasma supply source installed outside the processing chamber.
(8) The processing apparatus of any one of (1) to (7), further comprising:
a lifting mechanism configured to raise and lower the support portion; and
a controller configured to control the lifting mechanism to adjust a distance between the processing target object supported by the support part and the partitioning part of the shower structure.
(9) The processing apparatus of any one of (1) to (8), wherein the shower structure has a plurality of the first gas holes.
(10) A shower structure provided to face a processing target object supported by a support part in a processing chamber of a processing apparatus for processing a peripheral edge portion of the processing target object with plasma, the shower structure comprising:
a first gas hole formed in a first region facing a center of the processing target object supported by the support part and configured to discharge an inert gas;
a partitioning part having an annular shape in plan view, and configured to partition the first region from a second region surrounding an outer circumference of the first region at a position facing an outer peripheral portion of the processing target object supported by the support part; and
a second gas hole located in the second region and configured to discharge plasma,
wherein the partitioning part is formed to extend downward, and
the second gas hole is provided as a plurality of holes arranged in an annular shape along an outer circumference of the partitioning part in plan view, or formed in an annular shape along the outer circumference of the partitioning part in plan view.

1. A processing apparatus for processing a peripheral edge portion of a processing target object with plasma, comprising:
a processing chamber accommodating the processing target object;
a support part configured to support the processing target object in the processing chamber; and
a shower structure located to face the processing target object supported on the support part,
wherein the shower structure includes:
a first gas hole formed in a first region facing a center of the processing target object supported by the support part and configured to discharge an inert gas;
a partitioning part having an annular shape in plan view, and configured to partition the first region from a second region surrounding an outer circumference of the first region at a position facing an outer peripheral portion of the processing target object supported by the support part; and
a second gas hole located in the second region and configured to discharge plasma,
wherein the partitioning part is formed to extend downward, and
the second gas hole is provided as a plurality of holes arranged in an annular shape along an outer circumference of the partitioning part in plan view, or formed in an annular shape along the outer circumference of the partitioning part in plan view.

2. The processing apparatus of claim 1, wherein a distance from the second gas hole to the processing target object supported by the support part is longer than a distance from the first gas hole to the processing target object supported by the support part.

3. The processing apparatus of claim 1, wherein the shower structure further includes:
a channel connected to the second gas hole from the top,
wherein the channel is formed in a tapered shape that becomes narrow toward the second gas hole in cross-sectional view.

4. The processing apparatus of claim 1, wherein the shower structure further includes:
a plasma collecting portion formed in the second region to extend downward,
wherein the plasma collecting portion collectively surrounds the outer circumferences of the plurality of second gas holes arranged in an annular shape in plan view, or surrounds the outer circumference of the second gas hole formed in an annular shape in plan view.

5. The processing apparatus of claim 1, wherein the plurality of second gas holes are arranged in an annular shape along the outer circumference of the partitioning part in plan view,
the plurality of second gas holes include vertical holes and oblique holes,
the vertical holes discharge plasma vertically downward, and
the oblique holes discharge plasma obliquely downward, which is parallel to a tangential direction of a circle centered on the center of the processing target object supported by the support part at the positions of the oblique holes, in plan view.

6. The processing apparatus of claim 1, wherein the second gas hole is provided at a position that does not overlap the processing target object supported by the support in plan view.

7. The processing apparatus of claim 1, wherein the plasma is supplied from a remote plasma supply source installed outside the processing chamber.

8. The processing apparatus of claim 1, further comprising:
a lifting mechanism configured to raise and lower the support portion; and
a controller configured to control the lifting mechanism to adjust a distance between the processing target object supported by the support part and the partitioning part of the shower structure.

9. The processing apparatus of claim 1, wherein the shower structure has a plurality of the first gas holes.

10. A shower structure provided to face a processing target object supported by a support part in a processing chamber of a processing apparatus for processing a peripheral edge portion of the processing target object with plasma, the shower structure comprising:
a first gas hole formed in a first region facing a center of the processing target object supported by the support part and configured to discharge an inert gas;
a partitioning part having an annular shape in plan view, and configured to partition the first region from a second region surrounding an outer circumference of the first region at a position facing an outer peripheral portion of the processing target object supported by the support part; and
a second gas hole located in the second region and configured to discharge plasma,
wherein the partitioning part is formed to extend downward, and
the second gas hole is provided as a plurality of holes arranged in an annular shape along an outer circumference of the partitioning part in plan view, or formed in an annular shape along the outer circumference of the partitioning part in plan view.
